(19) United States
(12) Patent Application Publication
(10) Pub. No.: US 2026/0088121 A1
(43) Pub. Date: Mar. 26, 2026

(54) TEST SYSTEM AND METHOD FOR MEMORY PARAMETER CALIBRATION

(71) Applicant: Winbond Electronics Corp., Taichung City (TW)

(72) Inventor: Chih-Ying Chang, Miaoli County (TW)

(73) Assignee: Winbond Electronics Corp., Taichung City (TW)

(21) Appl. No.: 19/302,107

(22) Filed: Aug. 18, 2025

(30) Foreign Application Priority Data
Sep. 25, 2024 (TW) 113136464

(51) Int. Cl. G11C 29/56

(52) U.S. Cl. CPC G11C 29/56004; G11C 29/56012; G11C 29/56016; G11C 2029/5602

(57) ABSTRACT

A test system and a method for memory parameter calibration are provided. The test system includes a plurality of memory chips to be tested, a fixture, an input device, and a memory test device. The memory test device transmits a test command to the memory chips. Each memory chip includes a first test circuit block and a second test circuit block. The first test circuit block sequentially uses N test options to generate corresponding N original signal groups based on the test command and performs signal processing on each of the N original signal groups according to test parameters selected to be calibrated to generate N compensation amounts respectively corresponding to the N test options. The second test circuit block one by one filters for an optimal compensation amount from the N compensation amounts to provide a test option corresponding to the optimal compensation amount as a calibration test option.

### CROSS-REFERENCE TO RELATED APPLICATION

This application claims the priority benefit of Taiwan application serial no. 113136464, filed on Sep. 25, 2024. The entirety of the above-mentioned patent application is hereby incorporated by reference herein and made a part of this specification.

### BACKGROUND

### Technical Field

The disclosure relates to a test method for memory parameter self-calibration, and particularly relates to a test system and a method memory parameter calibration, which can be applied to shorten the test time.

### Description of Related Art

In the production of memory products, it is necessary to test signals generated by each packaged memory chip or die to determine whether the functionality is normal. For instance, the test involves a plurality of test parameters (including the TAC parameter, the TDQSCK parameter, the TDQSQ parameter, and the TQH parameter) for a clock signal (TCK), a data strobe signal (DQS), and a data signal (DQ) required for the operation of each memory chip, so as to analyze and identify an optimal test option (the best adjustment amount) based on the test results. The optimal test option obtained from the analysis may be burned into the corresponding memory chip through an e-fuse (E-Fuse), thereby optimizing the parameter performance of the memory chips.

However, since the optimal test option for each memory chip is not identical, current processes require scanning a large amount of test data by each memory chip for each test option. The data are collected and transmitted to an external memory test device for further data processing, which consumes significant scanning time and data processing time. Moreover, after analyzing and determining the optimal test options for all memory chips through data processing, all the optimal test options still need to be individually burned into the corresponding memory chips, adding substantial time to the burn-in process. Therefore, reducing the overall test time while keeping costs manageable has become an increasingly important challenge in the industry.

### SUMMARY

The disclosure provides a test system and a method for memory parameter calibration, which may eliminate the conventional time-consuming process for scanning parameter characteristics spent to find optimal parameter conditions and the time needed for external programs to process collected data of parameter characteristics. Once the optimal parameter conditions for all tested memories are determined, a single burn-in command is sufficient to complete the e-fuse burning for the optimal parameters of each memory, significantly reducing the overall burn-in time.

According to an embodiment of the disclosure, a memory parameter calibration test system includes a plurality of memory chips to be tested, a fixture, an input device, and a memory test device. The fixture is configured to hold the memory chips. The input device is configured to receive a test operation. The memory test device is coupled to the fixture and the input device and configured to set N test options in response to the test operation and transmit a test command to the memory chips, so as to sequentially adopt N test options to test the memory chips, where N is a positive integer greater than 1. Each of the memory chips includes a first test circuit block and a second test circuit block. The first test circuit block is configured to sequentially generate corresponding N original signal groups through adopting the N test options according to the test command and perform signal processing on each of the N original signal groups according to a test parameter selected to be calibrated, so as to generate N compensation amounts corresponding to the N test options respectively. The second test circuit block is coupled to the first test circuit block and configured to sequentially filter for an optimal compensation amount from the N compensation amounts, so as to provide a test option of the N test options corresponding to the optimal compensation amount as a calibration test option.

According to an embodiment of the disclosure, a memory parameter calibration test method includes following steps: setting N test options in response to a test operation, where N is a positive integer greater than 1; transmitting a test command to a plurality of memory chips to test the memory chips through sequentially adopting N test options; generating corresponding N original signal groups through sequentially adopting N test options according to the test command and performing signal processing on each of the N original signal groups according to a test parameter selected to be calibrated, so as to generate N compensation amounts corresponding to the N test options respectively; sequentially filtering for an optimal compensation amount from the N compensation amounts to provide a test option of the N test options corresponding to the optimal compensation amount as a calibration test option.

In view of the above, the test system and the method for the memory parameter calibration provided in one or more embodiments of the disclosure do not require complex processes (including scanning the parameter characteristics and collecting all test data, performing data processing, and so on) but may automatically find the most suitable calibration test option within each memory chip through a simple method. Each memory chip may further simultaneously burn in its own calibration test option, thus achieving self-calibration. As a result, the time spent in scanning the parameter characteristics and data processing may be eliminated, and the burn-in time for the optimal test option may also be reduced, thus significantly reducing the time spent on tests.

To make the above-mentioned features and advantages of the disclosure more apparent and understandable, exemplary embodiments are described below with reference to the accompanying drawings in detail as follows.

### BRIEF DESCRIPTION OF THE DRAWINGS

FIG. 1 is a schematic block diagram illustrating a memory parameter calibration test system according to an embodiment.

FIG. 2 is a schematic block diagram illustrating a memory chip according to an embodiment.

FIG. 3 is a schematic block diagram illustrating a first test circuit block according to an embodiment.

FIG. 4 illustrates an exemplary operation of a signal processor according to an embodiment.

FIG. 5 is a schematic partial circuit diagram illustrating a signal processor according to an embodiment.

FIG. 6A and FIG. 6B are schematic waveform diagrams illustrating data signals according to an embodiment.

FIG. 7A is a schematic partial circuit diagram illustrating a deviation adjustment device according to an embodiment.

FIG. 7B illustrates an exemplary delay time of a deviation adjustment device according to an embodiment.

FIG. 8A to FIG. 8D illustrate an exemplary operation of a phase detector according to an embodiment.

FIG. 9A is a schematic circuit diagram illustrating a phase amplifier according to an embodiment.

FIG. 9B is a schematic signal waveform diagram illustrating a phase amplifier according to an embodiment.

FIG. 10 is a schematic block diagram illustrating an integrator according to an embodiment.

FIG. 11 is a schematic circuit diagram illustrating a second test circuit block according to an embodiment.

FIG. 12 is a flowchart illustrating steps of a memory test method according to an embodiment.

### DESCRIPTION OF THE EMBODIMENTS

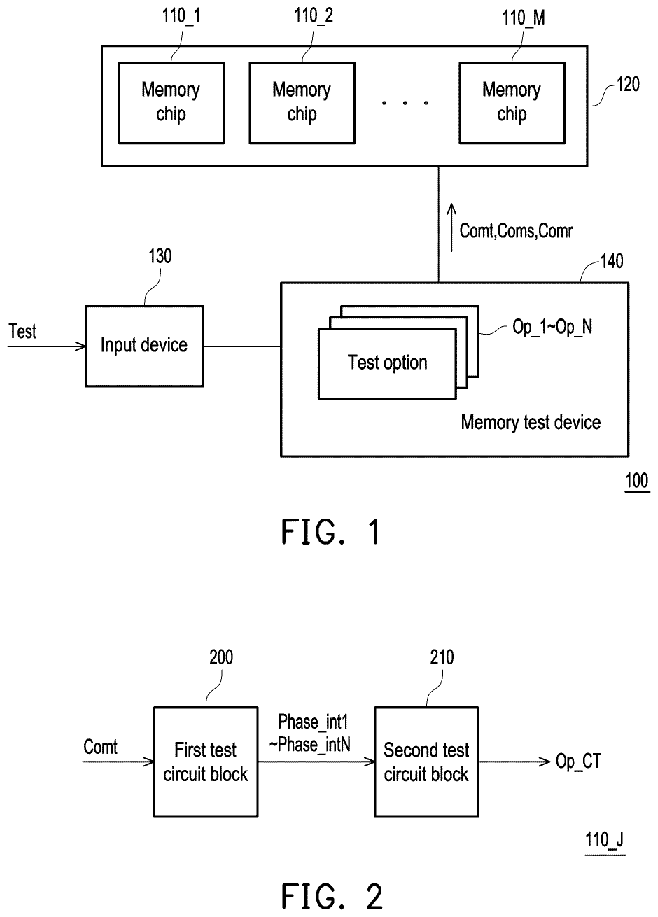

With reference to FIG. 1, a memory parameter calibration test system 100 provided in this embodiment includes memory chips 110_1 to 110_M to be tested, a fixture 120, an input device 130, and a memory test device 140.

The fixture 120 may hold M memory chips 110_1 to 110_M to be tested. Specifically, the fixture 120 may simultaneously hold all the memory chips 110_1 to 110_M to perform a test on the memory chips 110_1 to 110_M simultaneously. M is a positive integer greater than 1.

The input device 130 may, for instance, be a mouse, input keys, a remote controller, a touchpad, or a touch panel with resistive, capacitive, or other types of touch-sensing components, and the input device 130 may receive a test operation Test (such as selecting a test item, settings, and so on) performed by a user.

The memory test device 140 may, for instance, be a central processing unit (CPU) or another programmable general-purpose or special-purpose microprocessor, digital signal processor (DSP), programmable controller, application specific integrated circuit (ASIC), or any other similar element or combinations of the above elements. As shown in FIG. 1, the memory test device 140 is coupled to the fixture 120 and the input device 130. The memory test device 140 may set N test options Op_1 to Op_N in response to the test operation Test. N is a positive integer greater than 1. The test options Op_1 to Op_N provided in this embodiment are adjustment amounts of different values, respectively. For instance, the test options Op_1 to Op_N may be different time lengths in picoseconds from short to long, which may serve to adjust the time difference between signals generated by the memory chips 110_1 to 110_M. For instance, the first test option Op_1 may be 0 picosecond, the second test option Op_2 may be 20 picoseconds, the third test option Op_3 may be 40 picoseconds, and so on.

Moreover, the memory test device 140 may transmit a test command Comt to the memory chips 110_1 to 110_M, so as to perform a test on the memory chips 110_1 to 110_M through sequentially adopting N test options Op_1 to Op_N.

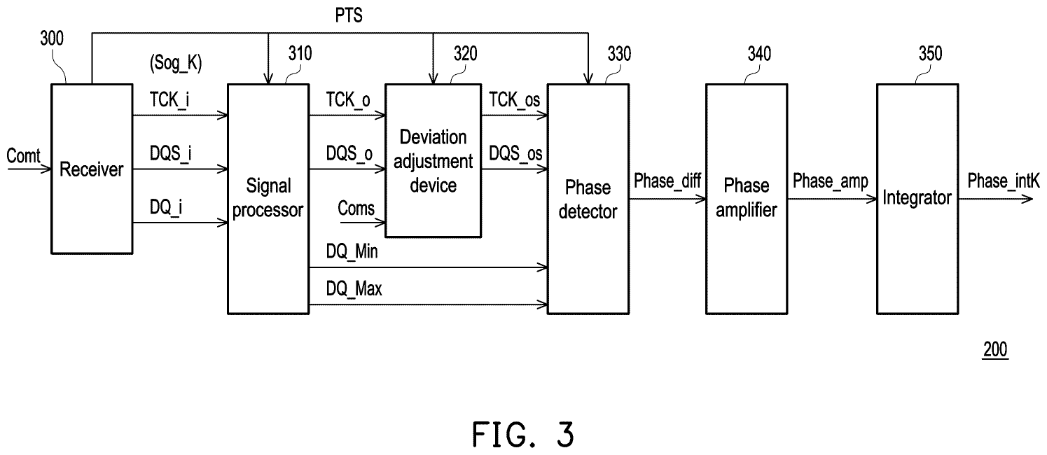

With reference to FIG. 2, in this embodiment, each of the memory chips 110_1 to 110_M (the memory chip 110_J) includes a first test circuit block 200 and a second test circuit block 210. J is any number between 1 and M.

The first test circuit block 200 may generate corresponding N original signal groups Sog_1 to Sog_N through sequentially adopting the N test options Op_1 to Op_N according to the test command Comt and perform signal processing on each of the original signal groups Sog_1 to Sog_N according to a test parameter PTS selected to be calibrated, so as to generate N compensation amounts Phase_int1 to Phase_intN corresponding to the N test options Op_1 to Op_N, respectively.

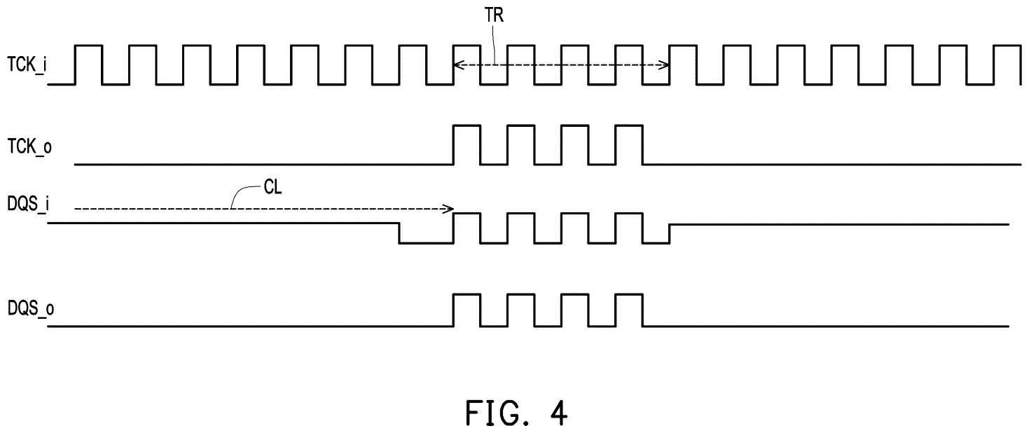

Specifically, with reference to FIG. 3, the first test circuit block 200 includes a receiver 300, a signal processor 310, a deviation adjustment device 320, a phase detector 330, a phase amplifier 340, and an integrator 350. The receiver 300 may receive the test command Comt and decode the test command Comt, so as to select the test parameter PTS to be calibrated from a plurality of test parameters (including a TAC parameter, a TDQSCK parameter, a TDQSQ parameter, and a TQH parameter) according to the test command Comt, and notify the signal processor 310, the deviation adjustment device 320, and the phase detector 330 of the test parameter PTS to be calibrated.

Moreover, the receiver 300 may generate the corresponding N original signal groups Sog_1 to Sog_N through sequentially adopting the N test options Op_1 to Op_N according to the test command Comt. Besides, when a test adopting the K^{th} test option Op_K of the N test options Op_1 to Op_N is performed, the receiver 300 may provide the K^{th} original signal group Sog_K corresponding to the K^{th} test option Op_K according to the test command Comt. K is any number between 1 and N. Each of the original signal groups Sog_1 to Sog_N (the K^{th} original signal group Sog_K) includes a first clock signal TCK_i, a first data strobe signal DQS_i, and a data signal group DQ_i.

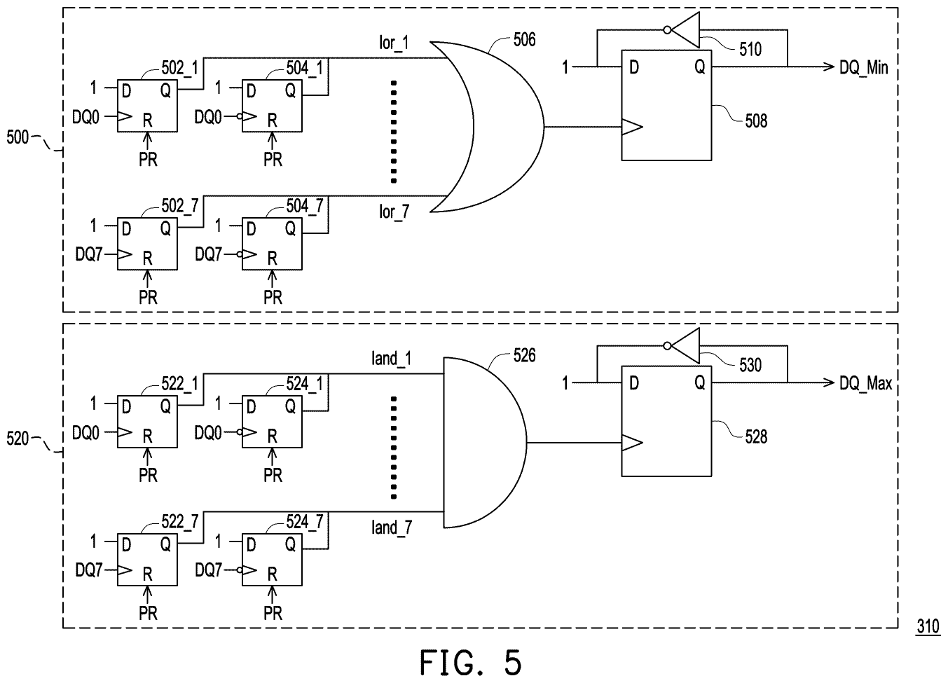

The signal processor 310 is coupled to the receiver 300. As shown in FIG. 4, the signal processor 310 may, according to the test parameter PTS to be calibrated, filter out a waveform outside a test range TR from the first clock signal TCK_i received and the first data strobe signal DQS_i received, and output them as a second clock signal TCK_o and a second data strobe signal DQS_o, respectively. In FIG. 4, the test range TR is, for instance, 4 clock cycles, and the test range TR may be determined according to the length of clock latency CL.

Moreover, the signal processor 310 may obtain and output an earliest data signal DQ_Min and a latest data signal DQ_Max within the test range TR from the data signal group DQ_i. For instance, the data signal group DQ_i includes data signals DQ0 to DQ7, and the signal processor 310 includes an earliest data signal generating circuit 500 and a latest data signal generating circuit 520.

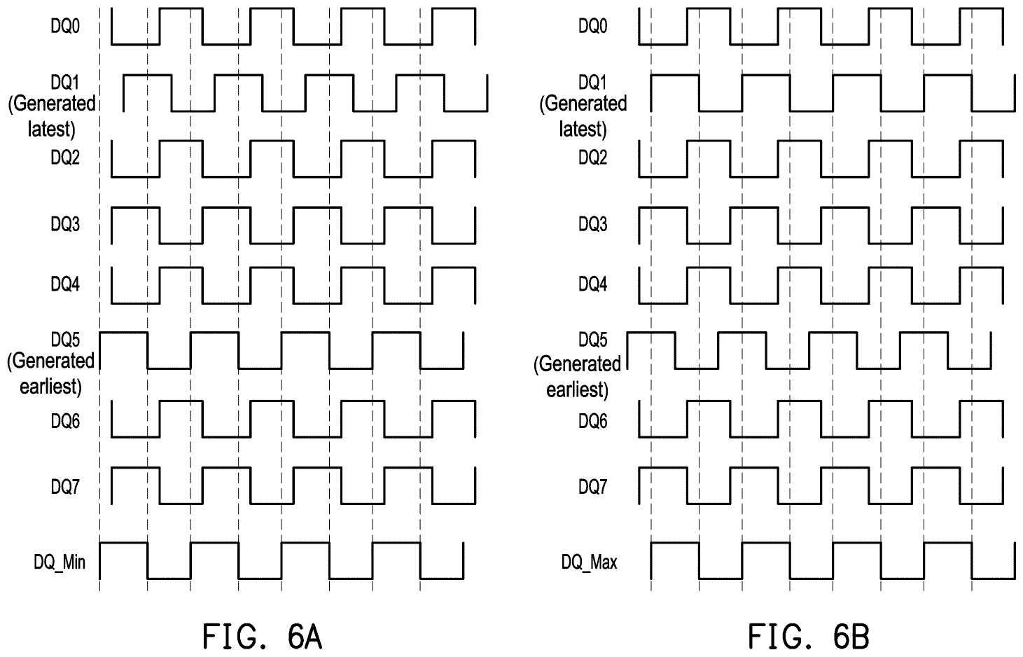

With reference to FIG. 5, the earliest data signal generating circuit 500 includes first flip-flops 502_1 to 502_7, second flip-flops 504_1 to 504_7, an OR gate 506, a third flip-flop 508, and an inverter 510. First input terminals of the first flip-flops 502_1 to 502_7 receive the data signals DQ0 to DQ7, respectively, while second input terminals of the first flip-flops 502_1 to 502_7 serve to receive a high logic level (logic 1) signal. Similarly, first input terminals of the second flip-flops 504_1 to 504_7 receive the data signals DQ0 to DQ7, respectively, while second input terminals of the second flip-flops 504_1 to 504_7 serve to receive a high logic level signal. The difference between the first flip-flops 502_1 to 502_7 and the second flip-flops 504_1 to 504_7 lies in that the first flip-flops 502_1 to 502_7 provide the high logic level signal to their output terminals in response to the non-inverted data signals DQ0 to DQ7, respectively, while the second flip-flops 504_1 to 504_7 provide the high logic level signal to their output terminals in response to the inverted data signals DQ0 to DQ7, respectively. The output terminals of the first flip-flops 502_1 to 502_7 and the second flip-flops 504_1 to 504_7 are respectively coupled to input terminals Ior_1 to Ior_7 of the OR gate 506, and an output terminal of the OR gate 506 is coupled to the first input terminal of the third flip-flop 508. An output terminal of the third flip-flop 508 is coupled to an input terminal of the inverter 510 and serves to generate the earliest data signal DQ_Min. A second input terminal of the third flip-flop 508 is coupled to an output terminal of the inverter 510 and serves to receive the high logic level signal.

Moreover, when the earliest data signal DQ_Min generated at the output terminal of the third flip-flop 508 undergoes a level change, third input terminals of the first flip-flops 502_1 to 502_7 and the second flip-flops 504_1 to 504_7 receive a reset signal PR to reset the logic levels at their output terminals.

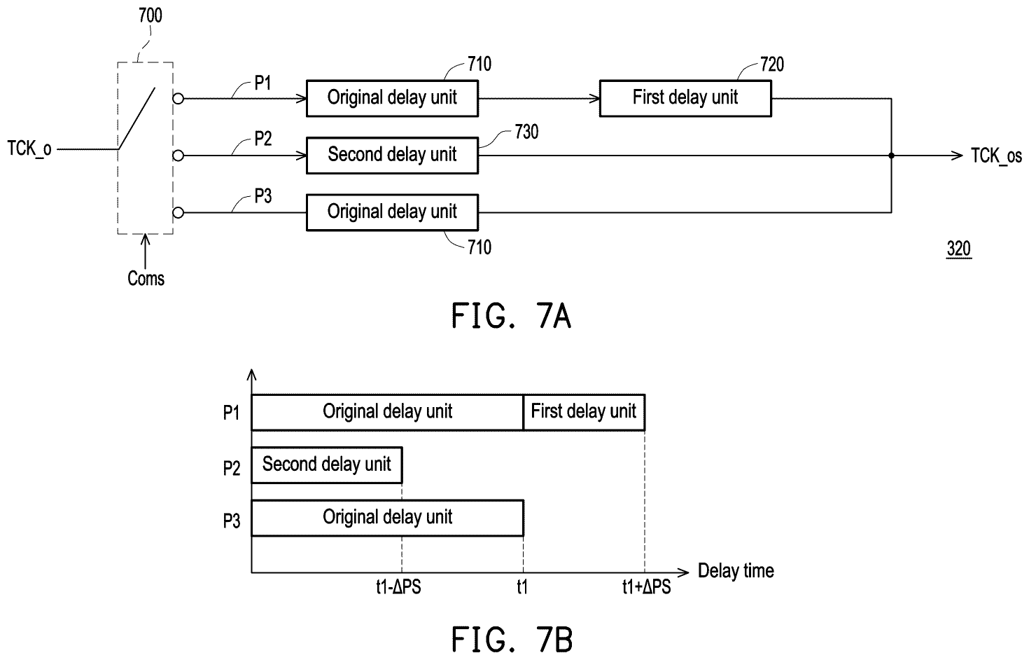

With reference to FIG. 6A, based on the circuit configuration of the earliest data signal generating circuit 500, the waveform of the earliest data signal DQ_Min is equivalent to the waveform of the data signal DQ5, which is the earliest generated signal among the data signals DQ0 to DQ7.

With reference to FIG. 5, the latest data signal generating circuit 520 includes fourth flip-flops 522_1 to 522_7, fifth flip-flops 524_1 to 5247, an AND gate 526, a sixth flip-flop 528, and an inverter 530. First input terminals of the fourth flip-flops 522_1 to 522_7 respectively receive the data signals DQ0 to DQ7, while second input terminals of the fourth flip-flops 522_1 to 522_7 serve to receive a high logic level (logic 1) signal. Similarly, first input terminals of the fifth flip-flops 524_1 to 524_7 respectively receive the data signals DQ0 to DQ7, while second input terminals of the fifth flip-flops 524_1 to 524_7 serve to receive a high logic level signal. The difference between the fourth flip-flops 522_1 to 522_7 and the fifth flip-flops 524_1 to 524_7 lies in that the fourth flip-flops 522_1 to 522_7 respectively provide a high logic level signal to their output terminals in response to the non-inverted data signals DQ0 to DQ7, while the fifth flip-flops 524_1 to 524_7 respectively provide a high logic level signal to their output terminals in response to the inverted data signals DQ0 to DQ7. The output terminals of the fourth flip-flops 522_1 to 522_7 and the output terminals of the fifth flip-flops 524_1 to 524_7 are respectively coupled to input terminals Iand_1 to Iand_7 of the AND gate 526, and an output terminal of the AND gate 526 is coupled to a first input terminal of the sixth flip-flop 528. An output terminal of the sixth flip-flop 528 is coupled to an input terminal of the inverter 530 and serves to generate the latest data signal DQ_Max. A second input terminal of the sixth flip-flop 528 is coupled to an output terminal of the inverter 530 and serves to receive a high logic level signal.

Moreover, when the latest data signal DQ_Max generated at the output terminal of the sixth flip-flop 528 undergoes a level change, third input terminals of the fourth flip-flops 522_1 to 522_7 and the fifth flip-flops 524_1 to 524_7 receive a reset signal PR to reset the logic levels at their output terminals.

With reference to FIG. 6B, based on the circuit configuration of the latest data signal generating circuit 520, the waveform of the latest data signal DQ_Max is equivalent to the waveform of the data signal DQ1, which is the latest generated signal among the data signals DQ0 to DQ7.

In FIG. 3, the deviation adjustment device 320 is coupled between the signal processor 310 and the phase detector 330. The deviation adjustment device 320 may, according to a deviation command Coms transmitted from the memory test device 140, adjust a delay amount (delay time) of the second clock signal TCK_o or the second data strobe signal DQS_o received from the signal processor 310 depending on the test parameter PTS to be calibrated, and output it as the second clock signal TCK_os or the second data strobe signal DQS_os to the phase detector 330. Specifically, when the TAC parameter or TDQSCK parameter is selected as the test parameter PTS to be calibrated, the deviation adjustment device 320 adjusts the delay amount (delay time) of the second clock signal TCK_o according to the deviation command Coms and output it as the second clock signal TCK_os. When the TDQSQ parameter or TQH parameter is selected as the test parameter PTS to be calibrated, the deviation adjustment device 320 adjusts the delay amount (delay time) of the second data strobe signal DQS_o according to the deviation command Coms and output it as the second data strobe signal DQS_os.

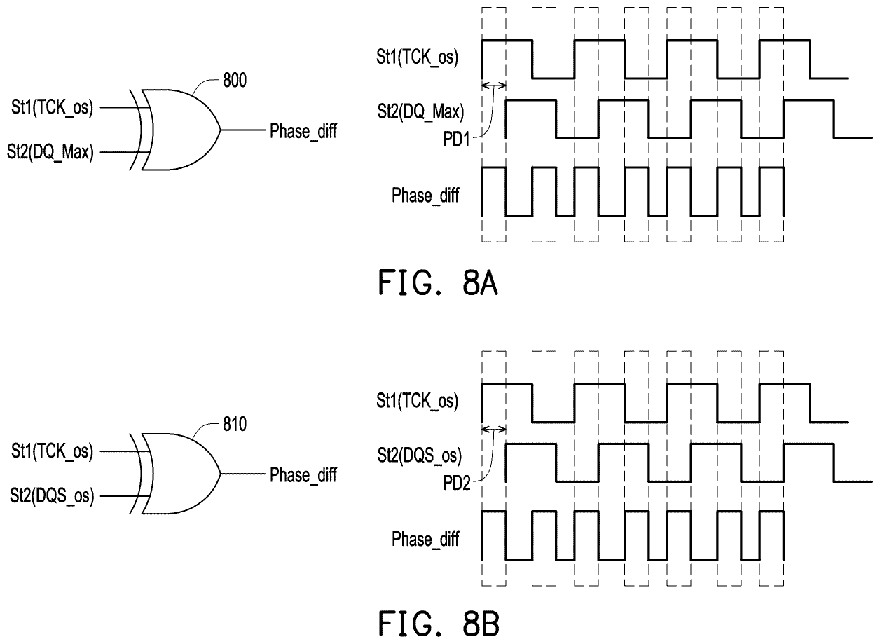

Moreover, for instance, with reference to both FIG. 7A and FIG. 7B, taking the adjustment of the second clock signal TCK_o as an example, the deviation adjustment device 320 includes a switch circuit 700. An input terminal of the switch circuit 700 serves to receive the second clock signal TCK_o, and a first output terminal to a third output terminal of the switch circuit 700 are coupled to a first path P1, a second path P2, and a third path P3, respectively. The first path P1 includes an original delay unit 710 and a first delay unit 720, the second path P2 includes a second delay unit 730, and the third path P3 includes the original delay unit 710. The horizontal axis in FIG. 7B represents the delay time. For instance, the delay time of the original delay unit 710 is t1, the delay time of the first delay unit 720 is ΔPS, and the delay time of the second delay unit 730 is t1−ΔPS. Therefore, the delay time generated on the first path P1 is t1+ΔPS, the delay time generated on the second path P2 is t1−ΔPS, and the delay time generated on the third path P3 is t1. However, the disclosure is not limited thereto.

A control terminal of the switch circuit 700 serves to receive the deviation command Coms. The switch circuit 700 may couple its input terminal to one of its first output terminal to third output terminal according to the deviation command Coms. In this embodiment, when the deviation command Coms indicates that the user needs to extend the delay time, the switch circuit 700 may couple its input terminal to its first output terminal to output the second clock signal TCK_os via the first path P1 with the delay time of t1+ΔPS. When the deviation command Coms indicates that the user needs to shorten the delay time, the switch circuit 700 may couple its input terminal to its second output terminal to output the second clock signal TCK_os via the second path P2 with the delay time of t1−ΔPS. When the deviation command Coms indicates that the delay time required by the user remains unchanged, the switch circuit 700 may couple its input terminal to its third output terminal to output the second clock signal TCK_os via the third path P3 with the delay time of t1. As such, the user may arbitrarily adjust the delay amount (delay time) of the signal through the deviation command Coms to meet specific requirements.

Similarly, the deviation adjustment device 320 may further include another switch circuit to adjust the delay amount (delay time) of the second data strobe signal DQS_o. The circuit structure provided herein may be the same as or similar to the circuit structure shown in FIG. 7 and thus will not be further elaborated hereinafter.

It should be noted that the disclosure does not impose limitations on the number of the selectable paths and the delay units in the above switch circuit. Those skilled in the pertinent art may, based on their actual requirements and referring to the teachings of this embodiment, appropriately adjust the number of the selectable paths for the switch circuit and the number or the delay amount of the delay units on each path.

In FIG. 3, the phase detector 330 is coupled to the deviation adjustment device 320. The phase detector 330 may select two signals as a first test signal St1 and a second test signal St2 from the second clock signal TCK_os received, the second data strobe signal DQS_os received, the earliest data signal DQ_Min received, and the latest data signal DQ_Max received according to the test parameter PTS to be calibrated. Moreover, the phase detector 330 may calculate the phase difference between the first test signal St1 and the second test signal St2 and provide a phase difference signal Phase_diff to represent the phase difference.

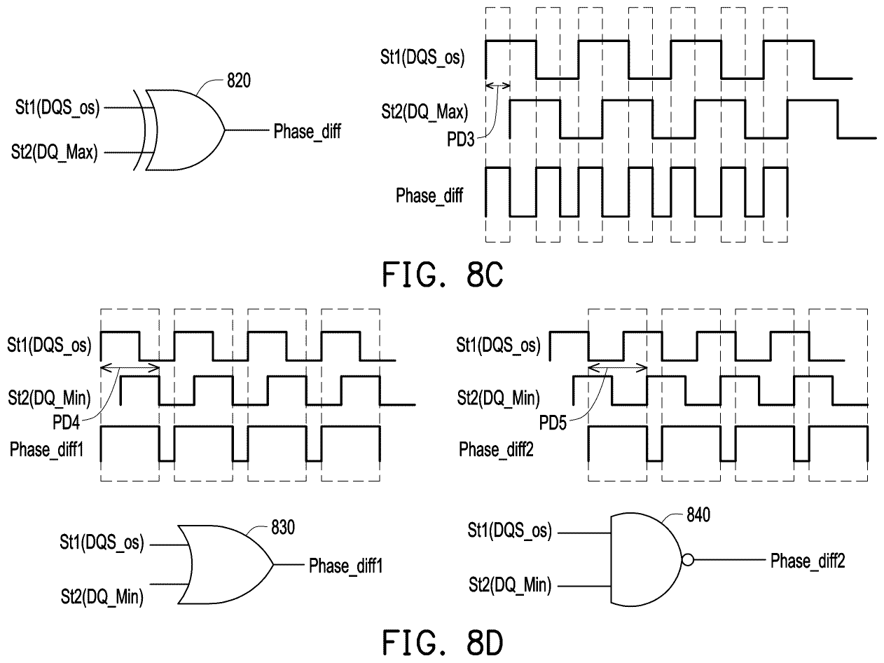

For instance, with reference to FIG. 8A to FIG. 8D. FIG. 8A illustrates an exemplary operation of the phase detector 330 when the TAC parameter is selected as the test parameter PTS to be calibrated. As shown in FIG. 8A, when the TAC parameter is selected as the test parameter PTS to be calibrated, the second clock signal TCK_os and the latest data signal DQ_Max are selected as the first test signal St1 and the second test signal St2, respectively. At this time, the phase detector 330 may perform an XOR operation on the first test signal St1 and the second test signal St2 through an internal XOR gate 800 to calculate a phase difference PD1 between the first test signal St1 and the second test signal St2 (the second clock signal TCK_os and the latest data signal DQ_Max) and provide the phase difference signal Phase_diff to represent the phase difference PD1.

FIG. 8B illustrates an exemplary operation of the phase detector 330 when the TDQSCK parameter is selected as the test parameter PTS to be calibrated. As shown in FIG. 8B, when the TDQSCK parameter is selected as the test parameter PTS to be calibrated, the second clock signal TCK_os and the second data strobe signal DQS_os are selected as the first test signal St1 and the second test signal St2, respectively. At this time, the phase detector 330 may perform an XOR operation on the first test signal St1 and the second test signal St2 through an internal XOR gate 810 to calculate a phase difference PD2 between the first test signal St1 and the second test signal St2 (the second clock signal TCK_os and the second data strobe signal DQS_os) and provide the phase difference signal Phase_diff to represent the phase difference PD2.

FIG. 8C illustrates an exemplary operation of the phase detector 330 when the TDQSQ parameter is selected as the test parameter PTS to be calibrated. As shown in FIG. 8C, when the TDQSQ parameter is selected as the test parameter PTS to be calibrated, the second data strobe signal DQS_os and the latest data signal DQ_Max are selected as the first test signal St1 and the second test signal St2, respectively. At this time, the phase detector 330 may perform an XOR operation on the first test signal St1 and the second test signal St2 through an internal XOR gate 820 to calculate a phase difference PD3 between the first test signal St1 and the second test signal St2 (the second data strobe signal DQS_os and the latest data signal DQ_Max) and provide the phase difference signal Phase_diff to represent the phase difference PD3.

FIG. 8D illustrates an exemplary operation of the phase detector 330 when the TQH parameter is selected as the test parameter PTS to be calibrated. As shown in FIG. 8D, when the TDQSQ parameter is selected as the test parameter PTS to be calibrated, the second data strobe signal DQS_os and the earliest data signal DQ_Min are selected as the first test signal St1 and the second test signal St2, respectively. At this time, the phase difference signal Phase_diff provided by the phase detector 330 includes the phase difference signals Phase_diff1 and Phase_diff2. The phase detector 330 may perform an OR operation on the first test signal St1 and the second test signal St2 through an internal OR gate 830 to calculate a phase difference PD4 between the first test signal St1 and the second test signal St2 (the second data strobe signal DQS_os and the earliest data signal DQ_Min) and provide the phase difference signal Phase_diff1 to represent the phase difference PD4. In addition, the phase detector 330 may perform a NAND operation on the first test signal St1 and the second test signal St2 through an internal NAND gate 840 to calculate a phase difference PD5 between the first test signal St1 and the second test signal St2 (the second data strobe signal DQS_os and the earliest data signal DQ_Min) and provide the phase difference signal Phase_diff2 to represent the phase difference PD5.

It should be noted that in this embodiment, four parameters, namely the TAC parameter, the TDQSCK parameter, the TDQSQ parameter, and the TQH parameter, act as examples for explanation, which should however not be construed as limitations in the disclosure. As long as the parameter is related to the phase difference between signals, those skilled in the pertinent art may make adjustment according to the actual needs based on the teachings of the disclosure to achieve parameter tests.

In FIG. 3, the phase amplifier 340 is coupled to the phase detector 330. The phase amplifier 340 may amplify the phase difference represented by the phase difference signal Phase_diff, and provide the amplified phase difference signal Phase_amp accordingly.

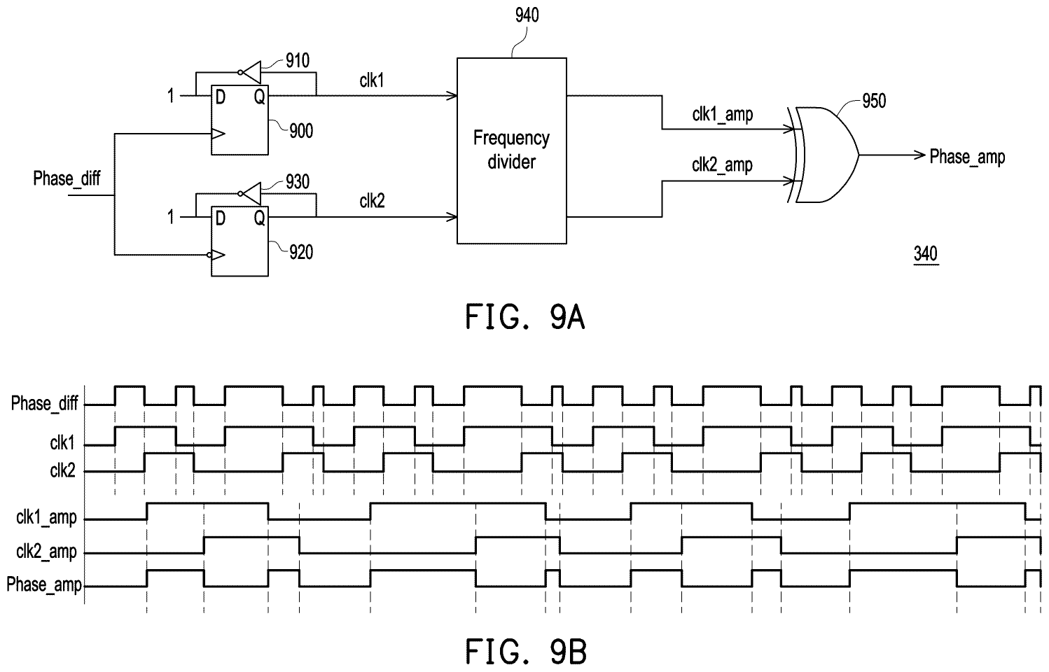

For instance, with reference to FIG. 9A, the phase amplifier 340 includes a flip-flop 900, an inverter 910, a flip-flop 920, an inverter 930, a frequency divider 940, and an XOR gate 950.

A first input terminal of the flip-flop 900 serves to receive the phase difference signal Phase_diff, while a second input terminal of the flip-flop 900 is coupled to an output terminal of the inverter 910 and serves to receive a high logic level signal. An output terminal of the flip-flop 900 is coupled to an input terminal of the inverter 910 and serves to generate a first phase difference clock signal clk1.

Similarly, a first input terminal of the flip-flop 920 serves to receive the phase difference signal Phase_diff, while a second input terminal of the flip-flop 920 is coupled to an output terminal of the inverter 930 and serves to receive a high logic level signal. An output terminal of the flip-flop 920 is coupled to an input terminal of the inverter 930 and serves to generate a second phase difference clock signal clk2. The difference between the flip-flop 900 and the flip-flop 920 lies in that the flip-flop 900 changes the logic level of the first phase difference clock signal clk1 at its output terminal in response to the non-inverted phase difference signal Phase_diff, while the flip-flop 920 changes the logic level of the second phase difference clock signal clk2 at its output terminal in response to the inverted phase difference signal Phase_diff.

The frequency divider 940 is coupled to the output terminal of the flip-flop 900 and the output terminal of the flip-flop 920. The frequency divider 940 may convert the first phase difference clock signal clk1 and the second phase difference clock signal clk2 into a first amplified phase difference clock signal clk1_amp and a second amplified phase difference clock signal clk2_amp respectively according to a preset amplification factor.

The XOR gate 950 is coupled to the frequency divider 940. The XOR gate 950 may perform an XOR operation on the first amplified phase difference clock signal clk1_amp and the second amplified phase difference clock signal clk2_amp to integrate them into an amplified phase difference signal Phase_amp, which represents the amplified phase difference. The waveform relationships among the phase difference signal Phase_diff, the first phase difference clock signal clk1, the second phase difference clock signal clk2, the first amplified phase difference clock signal clk1_amp, the second amplified phase difference clock signal clk2_amp, and the amplified phase difference signal Phase_amp may be referenced in FIG. 9B.

In an embodiment, since the clock cycle required for the amplified phase difference signal Phase_amp is longer than that required for the phase difference signal Phase_diff before amplification, the receiver 300 may set idle time between the time points of providing any two original signal groups based on the amplification factor adopted by the frequency divider 940, thereby avoiding errors.

In FIG. 3, the integrator 350 is coupled to the phase amplifier 340. The integrator 350 may sequentially integrate the amplified phase difference signals Phase_amp generated through adopting the N test options Op_1 to Op_N to sequentially analyze the N compensation amounts Phase_int1 to Phase_intN corresponding to the N test options Op_1 to Op_N, respectively. Besides, when the K^{th} test option Op_K of the N test options Op_1 to Op_N is adopted to perform the test, the integrator 350 may analyze a K^{th} compensation amount Phase_intK corresponding to the K^{th} test option Op_K.

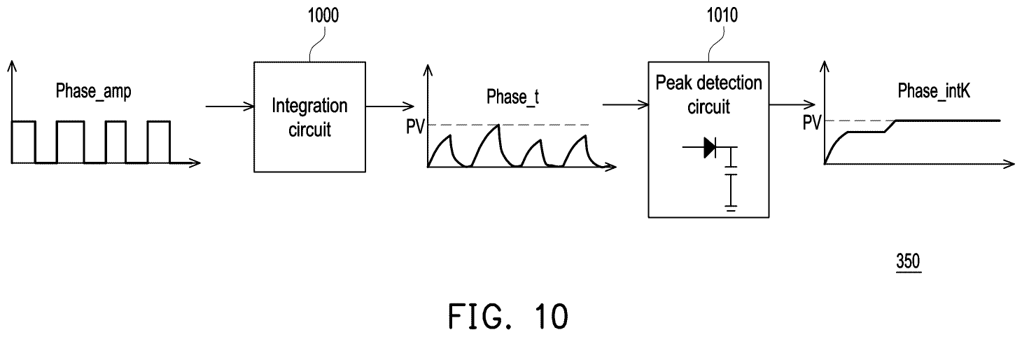

For instance, with reference to FIG. 10, the integrator 350 includes an integration circuit 1000 and a peak detection circuit 1010. The integration circuit 1000 may integrate the amplified phase difference signal Phase_amp to convert it into an integrated signal Phase_t. The integrator 350 may convert a square wave of the amplified phase difference signal Phase_amp into the waveform of the integrated signal Phase_t.

The peak detection circuit 1010 is coupled to the integration circuit 1000. The peak detection circuit 1010 may detect a peak value PV of the integrated signal Phase_t. When the K^{th} test option Op_K of the N test options Op_1 to Op_N is adopted to perform the test, the peak detection circuit 1010 may output the peak value PV as the corresponding K^{th} compensation amount Phase_intK. As shown in FIG. 10, the peak detection circuit 1010 may be constituted by, for instance, a diode and a capacitor, which should however not be construed as a limitation in the disclosure.

In FIG. 2, the second test circuit block 210 is coupled to the first test circuit block 200. The second test circuit block 210 may sequentially filter for the optimal compensation amount from the N compensation amounts Phase_int1 to Phase_intN to provide the test option corresponding to the optimal compensation amount as the calibration test option Op_CT.

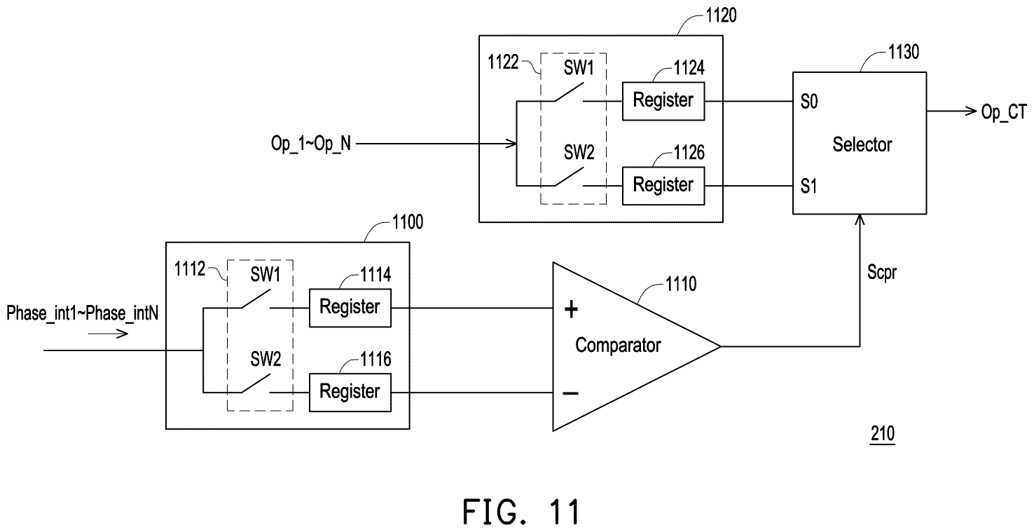

Specifically, with reference to FIG. 11, the second test circuit block 210 includes a first register circuit 1100, a comparator 1110, a second register circuit 1120, and a selector 1130. The first register circuit 1100 includes a switch circuit 1112, a register 1114, and a register 1116. When the N test options Op_1 to Op_N are sequentially adopted to test each of the memory chips 110_1 to 110_M, an input terminal of the first register circuit 1100 may sequentially receive the N compensation amounts Phase_int1 to Phase_intN.

The switch circuit 1112 is controlled by switch signals SW1 and SW2 to connect or disconnect the paths between the input terminal of the first register circuit 1100 and the registers 1114 and 1116. The first register circuit 1100 may simultaneously store two compensation amounts of the N compensation amounts Phase_int1 to Phase_intN in the registers 1114 and 1116.

The comparator 1110 is coupled to the first register circuit 1100. A non-inverted input terminal of the comparator 1110 is coupled to the register 1114, and an inverted input terminal of the comparator 1110 is coupled to the register 1116. The comparator 1110 compares the two compensation amounts stored in the first register circuit 1100 (the registers 1114 and 1116) and outputs a comparison signal Scpr accordingly.

The second register circuit 1120 includes a switch circuit 1122, a register 1124, and a register 1126. When the input terminal of the first register circuit 1100 sequentially receives the N compensation amounts Phase_int1 to Phase_intN, an input terminal of the second register circuit 1120 also sequentially receives the N test options Op_1 to Op_N. In other words, when the input terminal of the first register circuit 1100 receives the Km compensation amount Phase_intK, the input terminal of the second register circuit 1120 receives the Km test option Op_K.

The switch circuit 1122 is controlled by the switch signals SW1 and SW2 to connect or disconnect the paths between the input terminal of the second register circuit 1120 and the registers 1124 and 1126. The second register circuit 1120 may simultaneously store two test options corresponding to the two compensation amounts in the first register circuit 1100 in the registers 1124 and 1126.

The selector 1130 is coupled to the comparator 1110 and the second register circuit 1120. The selector 1130 may receive the comparison signal Scpr and select and output one of the two test options stored in the second register circuit 1120 based on the comparison signal Scpr. Specifically, in this embodiment, the N compensation amounts Phase_int1 to Phase_intN are the compensation amounts required for the time difference between signals when the test adopting the N test options Op_1 to Op_N is performed, respectively. The larger the compensation amount is, the less suitable the corresponding test option (the adjustment amount) is. For instance, when the compensation amount is 0, it represents that the adopted test option OP_K provides zero phase difference, and thus the test option OP_K is the optimal choice; by contrast, when the compensation amount is non-zero and is the largest among the N test options Op_1 to Op_N, it represents that the adopted test option OP_K leads to a relatively large phase difference, and therefore the adopted test option OP_K is the worst choice. When the comparison signal Scpr is logic 1, it indicates that the compensation amount stored in the register 1114 is greater than the compensation amount stored in the register 1116, which means that the compensation amount stored in the register 1116 is less and also represents a smaller phase difference, from which it may be derived that the test option stored in the register 1126 is better than the test option stored in the register 1124. At this time, the selector 1130 may select and output the test option stored in the register 1126 received from the input terminal S1 based on the comparison signal Scpr.

Conversely, when the comparison signal Scpr is logic 0, it indicates that the compensation amount stored in the register 1116 is greater than the compensation amount stored in the register 1114, which means that the compensation amount stored in the register 1114 is less and also represents a smaller phase difference, from which it may be derived that the test option stored in the register 1124 is better than the test option stored in the register 1126. At this time, the selector 1130 may select and output the test option stored in register 1124 received from the input terminal S0 based on the comparison signal Scpr.

To be specific, logic levels of the switch signals SW1 and SW2 may also be determined according to the logic level of the comparison signal Scpr. When the N test options Op_1 to Op_N are sequentially adopted to perform the test on each memory chip 110_1 to 110_M, the first register circuit 1100 first sequentially stores the first compensation amount Phase_int1 in the register 1114 and stores the second compensation amount Phase_int2 in the register 1116. When the next compensation amount (for instance, the third compensation amount Phase_int3) is continuously received, the first register circuit 1100 replaces the larger one of the two compensation amounts currently stored in the registers 1114 and 1116 with the next compensation amount for storage based on the comparison signal Scpr currently output by the comparator 1110, thus achieving the elimination of the weak and retention of the strong. For instance, when the comparison signal Scpr is logic 1, the switch signal SW1 is at a high logic level, the switch signal SW2 is at a low logic level, the path between the input terminal of the first register circuit 1100 and the register 1114 may be turned on, and the path between the input terminal of the first register circuit 1100 and the register 1116 may be disconnected, thereby replacing the compensation amount stored in the register 1114 with the next compensation amount. When the comparison signal Scpr is logic 0, the switch signal SW1 is at a low logic level, the switch signal SW2 is at a high logic level, the path between the input terminal of the first register circuit 1100 and the register 1114 may be disconnected, and the path between the input terminal of the first register circuit 1100 and the register 1116 may be turned on, thereby replacing the compensation amount stored in register 1116 with the next compensation amount. As such, the first register circuit 1100 may eliminate the inferior compensation amount and retain the superior compensation amount.

Similarly, the input terminals S0 and S1 of the selector 1130 may store the optimal test option in the registers 1124 and 1126 based on the replacement of the switch signals SW1 and SW2.

When the first register circuit 1100 stores the N^{th} compensation amount Phase_intN (i.e., the last compensation amount), the two compensation amounts stored in the registers 1114 and 1116 are the N^{th} compensation amount Phase_intN and the smallest (optimal) compensation amount among the previously received compensation amounts Phase_int1 to Phase_intN−1. At this time, the first register circuit 1100 selects the smaller one of the two compensation amounts currently stored in the registers 1114 and 1116 as the optimal compensation amount of the N compensation amounts Phase_int1 to Phase_intN based on the comparison signal Scpr currently output by the comparator 1110. Simultaneously, the selector 1130 may provide and output the test option corresponding to the optimal compensation amount as the calibration test option Op_CT based on the comparison signal Scpr.

After the test is performed on each memory chip 110_1 to 110_M through sequentially adopting the N test options Op_1 to Op_N, each of the memory chips 110_1 to 110_M has automatically found the most suitable test option from the N test options Op_1 to Op_N as its calibration test option Op_CT. Next, the memory test device 140 may transmit a burn-in command Comr to the memory chips 110_1 to 110_M, so that each of the memory chips 110_1 to 110_M simultaneously adopts its respective calibration test option Op_CT to perform burn-in through adopting the e-fuse, thereby effectively optimizing the parameter performance of each of the memory chips 110_1 to 110_M in a customized manner.

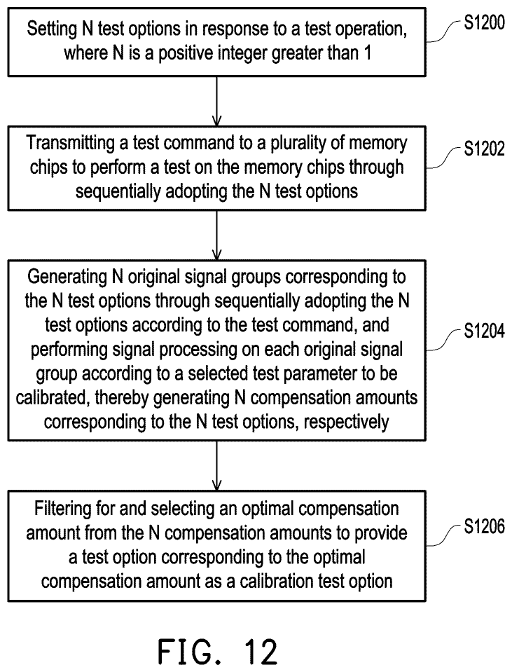

With reference to FIG. 12, in this embodiment, the memory test method includes following steps. In response to a test operation, N test options are set, where N is a positive integer greater than 1 (Step S1200). A test command is transmitted to a plurality of memory chips to perform a test on the memory chips through sequentially adopting the N test options (Step S1202). N original signal groups corresponding to the N test options are generated through sequentially adopting the N test options according to the test command, and signal processing on each original signal group is performed according to a selected test parameter to be calibrated, thereby generating N compensation amounts corresponding to the N test options, respectively (Step S1204). An optimal compensation amount is filtered and selected from the N compensation amounts to provide the test option corresponding to the optimal compensation amount as a calibration test option (Step S1206). Implementation details of the above steps S1200, S1202, S1204, and S1206 may be referenced in the embodiments depicted in FIG. 1 to FIG. 11 and thus will not be further elaborated hereinafter.

To sum up, the test system and the method for memory parameter calibration provided in one or more embodiments of the disclosure do not require complex processes but may automatically find the most suitable calibration test option within each memory chip through a simple method. Each memory chip may further simultaneously perform burn-in on its own calibration test option, thus achieving self-calibration and effectively optimizing the parameter performance of the memory chips. As a result, the time spent in scanning and the data processing time may be eliminated, and the burn-in time for the optimal test option may also be reduced. Compared to the known methods, the method provided herein significantly reduces the test time consumed and provides users with flexibility in designing test patterns.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory parameter calibration test system, comprising:
a plurality of memory chips to be tested;
a fixture, configured to hold the memory chips;
an input device, configured to receive a test operation; and
a memory test device, coupled to the fixture and the input device, configured to set N test options in response to the test operation, and transmitting a test command to the memory chips, so as to sequentially adopt the N test options to perform a test on the memory chips, wherein N is a positive integer greater than 1,
each of the memory chips comprises:
a first test circuit block, configured to sequentially generate corresponding N original signal groups through adopting the N test options according to the test command and perform signal processing on each of the N original signal groups according to a test parameter selected to be calibrated, so as to generate N compensation amounts respectively corresponding to the N test options; and
a second test circuit block, coupled to the first test circuit block and configured to sequentially filter for an optimal compensation amount from the N compensation amounts, so as to provide a test option of the N test options corresponding to the optimal compensation amount as a calibration test option.

2. The memory parameter calibration test system according to claim 1, wherein the first test circuit block comprises:
a receiver, configured to receive the test command, select the test parameter to be calibrated from a plurality of test parameters according to the test command, and when a test adopting a K^{th} test option of the N test options is performed, provide a K^{th} original signal group of the N original signal groups corresponding to the K^{th} test option, wherein each of the N original signal groups comprises a first clock signal, a first data strobe signal and a data signal group, wherein K is any number between 1 and N;
a signal processor, coupled to the receiver and configured to filter out a waveform outside a test range from the first clock signal received and the first data strobe signal received according to the test parameter selected to be calibrated, output the first clock signal filtered and the first data strobe signal filtered as a second clock signal and a second data strobe signal respectively, and obtain and output an earliest data signal and a latest data signal within the test range from the data signal group; and
a phase detector, coupled to the signal processor and configured to select two signals from the second clock signal received, the second data strobe signal received, the earliest data signal received, and the latest data signal received as a first test signal and a second test signal according to the test parameter selected to be calibrated, calculate a phase difference amount between the first test signal and the second test signal, and provide a phase difference signal representing the phase difference amount.

3. The memory parameter calibration test system according to claim 2, wherein the first test circuit block further comprises:
a deviation adjustment device, coupled between the signal processor and the phase detector and configured to adjust a delay amount of the second clock signal received or the second data strobe signal received according to a deviation command, depending on the test parameter selected to be calibrated, and output the delay amount to the phase detector.

4. The memory parameter calibration test system according to claim 2, wherein the first test circuit block further comprises:
a phase amplifier, coupled to the phase detector and configured to amplify the phase difference amount represented by the phase difference signal and provide an amplified phase difference signal accordingly; and
an integrator, coupled to the phase amplifier and configured to integrate the amplified phase difference signal, so as to analyze and determine a K^{th} compensation amount corresponding to the K^{th} test option when the test adopting the K^{th} test option is performed.

5. The memory parameter calibration test system according to claim 4, wherein the phase amplifier comprises:
a first flip-flop, having a first input terminal for receiving the phase difference signal, a second input terminal for receiving a high logic level signal, and an output terminal for generating a first phase difference clock signal, and configured to change a logic level of the first phase difference clock signal at the output terminal in response to the phase difference signal;
a first inverter, having an input terminal coupled to the output terminal of the first flip-flop and an output terminal coupled to the second input terminal of the first flip-flop;
a second flip-flop, having a first input terminal for receiving the phase difference signal, a second input terminal for receiving the high logic level signal, and an output terminal for generating a second phase difference clock signal, and configured to change a logic level of the second phase difference clock signal at the output terminal in response to the phase difference signal which is inverted;
a second inverter, having an input terminal coupled to the output terminal of the second flip-flop and an output terminal coupled to the second input terminal of the second flip-flop;
a frequency divider, coupled to the output terminal of the first flip-flop and the output terminal of the second flip-flop and configured to convert the first phase difference clock signal and the second phase difference clock signal into a first amplified phase difference clock signal and a second amplified phase difference clock signal respectively according to an amplification factor; and
an XOR gate, coupled to the frequency divider and configured to perform an XOR operation on the first amplified phase difference clock signal and the second amplified phase difference clock signal, so as to integrate the first amplified phase difference clock signal and the second amplified phase difference clock signal into the amplified phase difference signal.

6. The memory parameter calibration test system according to claim 5, wherein the receiver sets idle time between time points of providing two of the N original signal groups according to the amplification factor.

7. The memory parameter calibration test system according to claim 4, wherein the integrator comprises:
an integration circuit, configured to integrate the amplified phase difference signal to convert the amplified phase difference signal integrated into an integrated signal; and
a peak detection circuit, coupled to the integration circuit and configured to detect a peak value of the integrated signal to output the peak value as a corresponding compensation amount of the N compensation amounts.

8. The memory parameter calibration test system according to claim 1, wherein the second test circuit block comprises:
a first register circuit, configured to store two of the compensation amounts;
a comparator, coupled to the first register circuit and configured to compare the two compensation amounts stored in the first register circuit and output a comparison signal accordingly;
a second register circuit, configured to store two of the test options corresponding to the two compensation amounts in the first register circuit; and
a selector, coupled to the comparator and the second register circuit and configured to receive the comparison signal and select and output one of the two test options stored in the second register circuit according to the comparison signal.

9. The memory parameter calibration test system according to claim 8, wherein the first register circuit sequentially stores a first compensation amount and a second compensation amount of the N compensation amounts, and when a next compensation amount of the N compensation amounts is continuously received, the first register circuit replaces the larger one of the two stored compensation amounts with the next compensation amount and store the next compensation amount according to the comparison signal currently output by the comparator.

10. The memory parameter calibration test system according to claim 9, wherein when the first register circuit stores an N^{th} compensation amount of the N compensation amounts, the first register circuit selects the smaller one of the two stored compensation amounts as the optimal compensation amount according to the comparison signal currently output by the comparator, and the selector provides the test option corresponding to the optimal compensation amount as the calibration test option according to the comparison signal.

11. The memory parameter calibration test system according to claim 1, wherein the memory test device transmits a burn-in command to the memory chips, so as to enable each of the memory chips to simultaneously perform burn-in adopting respective calibration test options of the memory chips.

12. A memory test method, comprising:
setting N test options in response to a test operation, wherein N is a positive integer greater than 1;
transmitting a test command to a plurality of memory chips to perform a test on the memory chips through sequentially adopting the N test options;
sequentially generating N original signal groups corresponding to the N test options according to the test command and performing signal processing on each of the N original signal groups according to a test parameter selected to be calibrated, so as to generate N compensation amounts respectively corresponding to the N test options; and
sequentially filtering for an optimal compensation amount from the N compensation amounts to provide a test option of the N test options corresponding to the optimal compensation amount as a calibration test option.

13. The memory test method according to claim 12, wherein the step of sequentially generating the N original signal groups corresponding to the N test options according to the test command and performing the signal processing on each of the N original signal groups according to the test parameter selected to be calibrated to generate the N compensation amounts respectively corresponding to the N test options comprises:
receiving the test command, selecting the test parameter to be calibrated from a plurality of test parameters according to the test command, and when a test adopting a K^{th} test option is performed, providing a K^{th} original signal group of the N original signal groups corresponding to the K^{th} test option, wherein each of the N original signal groups comprises a first clock signal, a first data strobe signal, and a data signal group, wherein K is any number between 1 and N;
according to the test parameter selected to be calibrated, filtering out a waveform outside a test range from the first clock signal received and the first data strobe signal received, outputting the first clock signal filtered and the first data strobe signal filtered as a second clock signal and a second data strobe signal respectively, and obtaining and outputting an earliest data signal and a latest data signal within the test range from the data signal group;
according to the test parameter selected to be calibrated, selecting two signals from the second clock signal received, the second data strobe signal received, the earliest data signal received, and the latest data signal received as a first test signal and a second test signal, calculating a phase difference amount between the first test signal and the second test signal, and providing a phase difference signal representing the phase difference amount;
amplifying the phase difference amount represented by the phase difference signal and providing an amplified phase difference signal accordingly; and
integrating the amplified phase difference signal to analyze and determine a K^{th} compensation amount corresponding to the K^{th} test option when the test adopting the K^{th} test option is performed.

14. The memory test method according to claim 13, wherein the step of sequentially generating the N original signal groups corresponding to the N test options according to the test command and performing the signal processing on each of the N original signal groups according to the test parameter selected to be calibrated to generate the N compensation amounts respectively corresponding to the N test options further comprises:
according to a deviation command, adjusting a delay amount of the second clock signal received or the second data strobe signal received depending on the test parameter selected to be calibrated and outputting the delay amount.

15. The memory test method according to claim 13, wherein the step of amplifying the phase difference amount represented by the phase difference signal and providing the amplified phase difference signal accordingly comprises:
changing a logic level of a first phase difference clock signal in response to the phase difference signal;
changing a logic level of a second phase difference clock signal in response to the phase difference signal which is inverted;
according to an amplification factor, converting the first phase difference clock signal and the second phase difference clock signal into a first amplified phase difference clock signal and a second amplified phase difference clock signal respectively; and
performing an XOR operation on the first amplified phase difference clock signal and the second amplified phase difference clock signal to integrate the first amplified phase difference clock signal and the second amplified phase difference clock signal into the amplified phase difference signal.

16. The memory test method according to claim 13, wherein the step of providing the K^{th} original signal group corresponding to the K^{th} test option comprises:
integrating the amplified phase difference signal to convert it into an integrated signal; and
detecting a peak value of the integrated signal and outputting the peak value as a corresponding compensation amount of the N compensation amounts.

17. The memory test method according to claim 12, wherein the step of sequentially filtering for the optimal compensation amount from the N compensation amounts to provide the test option corresponding to the optimal compensation amount as the calibration test option comprises:
storing two of the compensation amounts in a first register circuit;
comparing the two compensation amounts stored in the first register circuit and outputting a comparison signal accordingly;
storing two of the test options corresponding to the two compensation amounts in the first register circuit in a second register circuit; and
selecting and outputting one of the two test options stored in the second register circuit according to the comparison signal.

18. The memory test method according to claim 17, wherein the step of storing two of the compensation amounts in the first register circuit includes:
sequentially storing a first compensation amount and a second compensation amount of the N compensation amounts in the first register circuit first; and
when a next compensation amount of the N compensation amounts is continuously received, replacing the larger one of the two compensation amounts stored in the first register circuit with the next compensation amount and storing the next compensation amount according to the comparison signal currently outputted.

19. The memory test method according to claim 18, wherein the step of sequentially filtering for the optimal compensation amount from the N compensation amounts to provide the test option corresponding to the optimal compensation amount as the calibration test option further comprises:
when storing an N^{th} compensation amount of the N compensation amounts in the first register circuit, selecting the smaller one of the two compensation amounts stored in the first register circuit as the optimal compensation amount according to the comparison signal currently outputted; and
providing the test option corresponding to the optimal compensation amount as the calibration test option according to the comparison signal.

20. The memory test method according to claim 12, further comprising:
transmitting a burn-in command to the memory chips, so as to enable each of the memory chips to simultaneously perform burn-in adopting respective calibration test options of the memory chips.
